(19) United States
(12) Patent Application Publication
(10) Pub. No.: US 2006/0091909 A1
(43) Pub. Date: May 4, 2006

(54) Energy conserving, digital circuit driving a transmission line

(76) Inventor: Soren Richard Fauerskov Laursen, Alleroed (DK)

Correspondence Address: Soeren R. F. Laursen, Skolelodden 14, Alleroed, DK - 3450, DK

(21) Appl. No.: 10/978,518

(22) Filed: Nov. 2, 2004

(51) Int. Cl. H03K 19/094

(52) U.S. Cl. 326/83

(57) ABSTRACT

In a digital system a circuit differentially drives a transmission line, which is open or lightly loaded at the receiving end. A change from a logical ‘1’ to a logical ‘0’ or vice versa is initiated by shorting the two conductors of the transmission line at the transmitting end. A wave then propagates towards the receiver where it is reflected. Just before the reflected wave returns to the drive circuit, the drive circuit is reconfigured in two steps. In the first step each conductor is connected through a matching impedance to the new potential finally required for that conductor. In the second step the short between the two conductors is removed. When the reflected wave reaches the driver, the transfer of charge is complete. Most of the charge required for the change has then been transferred directly from one conductor to the other instead of being sourced by the external power supply.

### BACKGROUND OF THE INVENTION

The present invention relates to a method and/or architecture for implementing digital, differential drive circuits generally and, particularly, to a method and/or architecture for implementing digital, differential drive circuits that drive transmission lines using less energy than traditional methods/architectures.

Referring to FIG. 1, item 100 is a conventional, digital, differential driver consisting of 4 switches, M1, M2 and M3, M4 driving the two conductors of the transmission line, item 150. The switches may be implemented as MOS transistors within an integrated CMOS circuit. Incident wave switching is employed. Both the transmitting end (item 100) and the receiving end (item 200) are impedance matched to avoid reflections. Referring to FIG. 1, R1 and R2 are the matched impedances at the transmitting end. The nominal value of R1 and R2 is Z₀/2 where Z₀ is the characteristic impedance of the transmission line. R3 is the matched termination resistor at the receiving end with a nominal value equal to Z₀.

In operation a logical ‘1’ is established by closing switches M1 and M4 and opening switches M2 and M3. A logical ‘0’ is established by closing M2, M3 and opening M1, M4.

A typical voltage difference between the two conductors of the transmission line is 0.35V and a typical characteristic impedance, Z₀, is 100 Ohms. It follows that such a circuit dissipates around 2.5 mW in the terminating resistors independently of the activity. To this must be added other losses in the driving circuit. In applications where power is a concern—for example in battery powered devices—a circuit like the one of FIG. 1 may not be well suited. Such devices typically conserve power by slowing down or shutting down circuits when they are not needed.

Referring to FIG. 2 the terminating resistor at the receiving end can be removed. The operation of the circuit then relies on the reflection of the wave at the receiver. Comparing with the circuit of FIG. 1 the voltage difference at the receiver doubles and the static power consumption becomes zero. A disadvantage is that the maximum signaling speed is now limited by the travel time of the wave. The wave must be reflected and returned to the transmitter before the next transition can be initiated. In low-power applications this may be acceptable however.

### BRIEF SUMMARY OF THE INVENTION

In a digital system a circuit differentially drives a transmission line, which is open or lightly loaded at the receiving end. A logical ‘1’ is represented by conductor ‘A’ having the potential Vhi and the other conductor ‘B’ having the potential Vlo. A logical ‘0’ is represented by conductor ‘A’ having the potential Vlo and conductor B having the potential Vhi.

A change from a logical ‘1’ to a logical ‘0’ or vice versa is initiated by shorting the two conductors of the transmission line at the transmitting end. A wave then propagates towards the receiver where it is reflected. Just before the reflected wave returns to the drive circuit, the drive circuit is reconfigured in two steps. In the first step each conductor is connected through a matching impedance to the new potential finally required for that conductor. In the second step the short between the two conductors is removed. When the reflected wave reaches the driver, the transfer of charge is complete and most of the charge required for the change has then been transferred directly from one conductor to the other instead of being sourced by the external power supply.

In systems where power consumption must be minimized and where the signaling speed is moderate, the invention enables considerable savings in power when compared with conventional methods. The invention is particularly suited for low-power systems where the transmission line lengths are more than, say, 20 cm and where the required signaling speed is less than, say, 50/L Mbps, L being the length of the transmission line in meters.

### BRIEF DESCRIPTION OF THE DRAWINGS

FIG. 1 shows the schematic for a conventional, differentially driven transmission line with matching terminations at both ends.

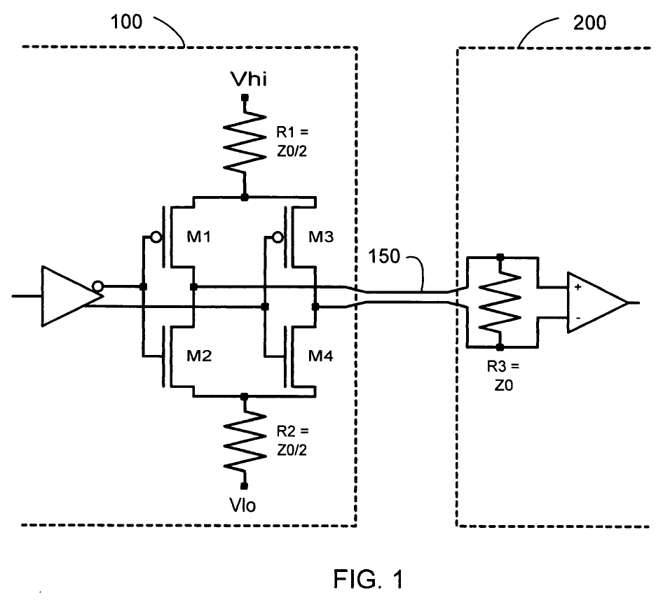

FIG. 2 shows the schematic for a conventional, differentially driven transmission line with matching termination at the transmitter and a high impedance load at the receiver.

FIG. 3 is a block diagram showing a preferred embodiment of the invented circuit.

FIG. 4 shows results of simulating the invented circuit.

### DETAILED DESCRIPTION OF THE INVENTION

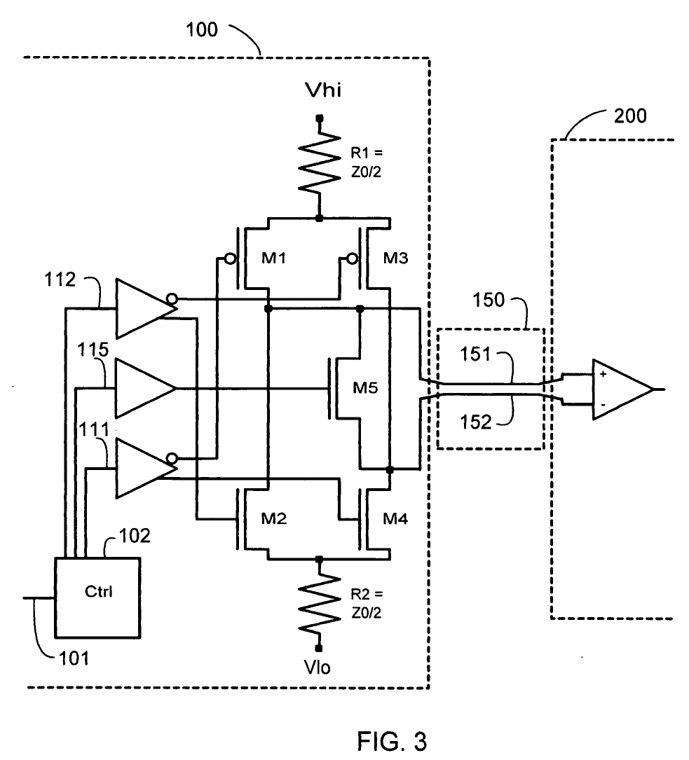

FIG. 3 depicts a preferred embodiment of the invention. Referring to FIG. 3, a circuit ‘100’ differentially drives a transmission line ‘150’ in a digital system. The transmission line is open or lightly loaded at the receiving end ‘200’. A logical ‘1’ is represented by conductor ‘151’ having the potential Vhi and the other conductor ‘152’ having the potential Vlo. A logical ‘0’ is represented by conductor ‘151’ having the potential Vlo and conductor ‘152’ having the potential Vhi.

The input signal ‘101’ stimulates the control logic ‘102’ to open and close the switches M1, M2, M3, M4 and M5. Switches M1 and M4 open and close together controlled by the signal ‘111’, switches M2 and M3 open and close together controlled by the signal ‘112’ and the switch M5 opens and closes controlled by the signal ‘115’.

The transmission line has the characteristic impedance Z₀. The terminating resistor R1 has a resistance such that the paths that may be established by M1 and M3 to Vhi have a resistance Z₀/2. Likewise R2 has a resistance such that the paths that may be established to Vlo by the switches M2 and M4 have a resistance Z₀/2. It is obvious that the resistance may be intrinsic to the switches and that, for example, 2 separate resistors, one in series with M1 and one in series with M4 could replace R1. The switch M5 has an intrinsic series resistance significantly lower than Z₀. Ideally it shorts the conductors ‘151’ and ‘152’ when closed.

When a logical ‘0’ is signaled steadily, switches M2 and M3 are closed and switches M1, M4 and M5 are open. When a logical ‘1’ is signaled steadily, switches M1 and M4 are closed and switches M2, M3 and M5 are open.

A change from a logical ‘0’ to a logical ‘1’ is accomplished by
Opening switches M2 and M3 and closing switch M5, causing a wave to begin propagating towards the receiver ‘200’.
Waiting a period until just before wave reflected at the open receiver end ‘200’ returns to the transmitter.
Closing switches M1 and M4.
Open switch M5, still before the reflected wave has returned.

A change from a logical ‘1’ to a logical ‘0’ is accomplished by
Opening switches M1 and M4 and closing switch M5, causing a wave to begin propagating towards the receiver ‘200’.
Waiting a period until just before wave reflected at the open receiver end ‘200’ returns to the transmitter.
Closing switches M2 and M3.
Open switch M5, still before the reflected wave has returned.

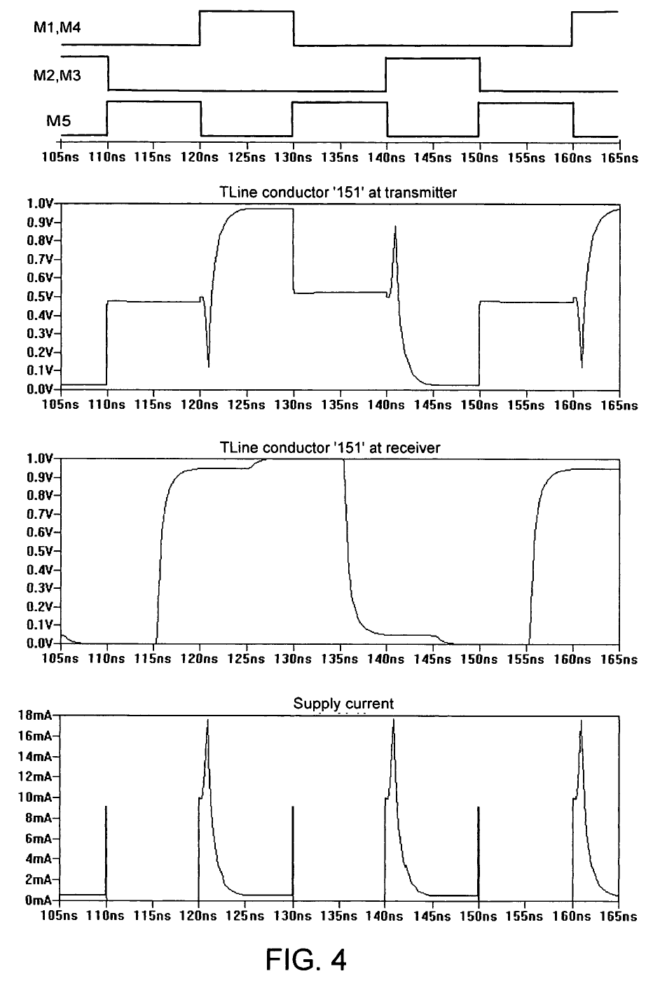

FIG. 4 shows results obtained by simulating the circuit of FIG. 3. To better model a realistic circuit including some of the inevitable deviations from the perfect situation, the following parameters where used:
Vhi is 1 V and Vlo is 0V.
The transmission line length is 1 m, its capacitance per unit length is 55 pF, its inductance per unit length is 550 nH and its resistance per unit length is 1 Ohm. The characteristic impedance Z₀ is then approximately 100 Ohms.
Switches M1, M4 have a series resistance of 50 Ohms to Vhi when closed and switches M2, M3 have a series resistance of 50 Ohms to Vlo when closed.
The switch M5 has an intrinsic resistance of 5 Ohms when closed. This is a deviation from the perfect short.
The receiving end is represented by a parasitic capacitance of 5 pF. This is a deviation from the ideal open.

The simulated input is a periodic signal that toggles every 20 ns. FIG. 3 and FIG. 4 are referenced in the following. At time 109.9 ns a change ‘0’->‘1’ is initiated by shorting M5. Shortly after at time 110 ns, switches M2 and M3 are opened as depicted in the waveforms marked ‘M5’ and ‘M2,M3’ of FIG. 4. During the short overlap, current is drawn from the supply as shown in the bottom waveform of FIG. 4. Whether M2,M3 are opened before or after closing M5 is not important. If opening M2,M3 after closing M5, then the overlap should be kept short however. Approximately 6 ns later at 116 ns the wave reaches the receiver and is reflected. Because of the light load at the receiver, the voltage swing doubles, resulting in a difference of about 0.9V being reached at around 119 ns. This can be seen at the waveform showing conductor ‘151's voltage at the receiver. At time 119 ns the difference isn't quite 1 V yet. M5 isn't a perfect short so the amplitude of the wave isn't quite (Vhi−Vlo)/2. This can also be seen at the waveform of conductor 151's voltage at the transmitter. At time 120 ns switches M1,M4 are closed and at time 120.1 ns switch M5 is opened to remove the short. The reflected wave still hasn't reached the transmitter. The closing of M1,M4 causes the voltage of conductor 151 to briefly rise to 0.5V again showing that the switch M5 isn't a perfect conductor. When the reflected wave returns at time 121 ns, there is a negative voltage spike. This is caused by the small parasitic SpF load modeled at the receiver. The imperfections cause the current flow visible in the supply current waveform of FIG. 4. Between time 120 ns and until the next change ‘1’->‘0’ is initiated at time 129.9 ns, the transmission line receives the remaining charge. At around time 127 ns the full difference is reached at the receiver.

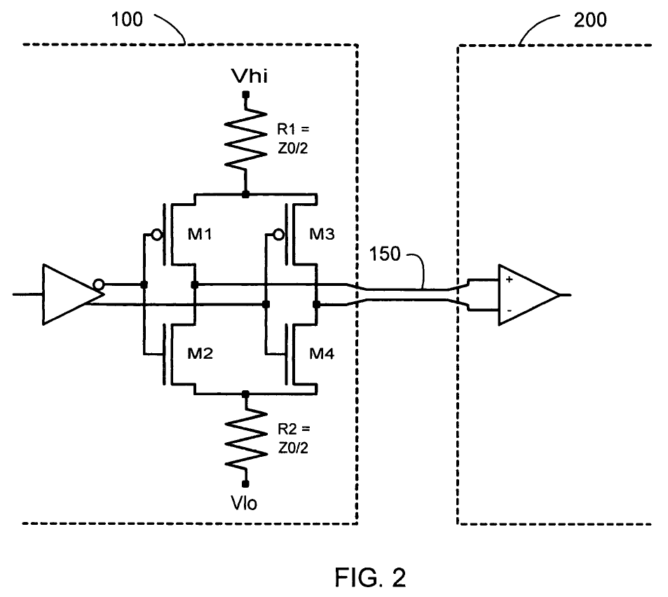

With the modeled circuit, the energy required to accomplish a change ‘0’->‘1’ or vice versa can be found by integrating the supply current shown in FIG. 4. The energy is thereby estimated to be approximately 35 pJ. Similar calculations for the conventional circuit of FIG. 2 yield a value of 130 pJ. The invention thus allows power to be reduced to ⅓^{rd} when compared with the circuit of FIG. 2.

The control logic block depicted in FIG. 3 can be implemented in various ways. In a preferred embodiment the voltages of the conductors 151 and 152 are sensed at the transmitting end. The travel time for the wave can thus be measured and the measured time saved. The measured value can then be used subsequently. By doing so during operation, variations caused by physical layout, temperature voltage and process can be accommodated. Methods to measure the time and subsequently use the measured value are known by people skilled in art.

In some cases the transmission line is physically divided into two parallel transmission lines, where each of the conductors 151 and 152 of FIG. 3 couples to a common ground plane or to grounded shields instead of coupling directly to the other conductor. When these two transmission lines have similar lengths and when the characteristic impedance of each is Z₀/2, then it is clear for people skilled in the art that the circuit is electrically equivalent to the invented circuit as described herein.

What is claimed is:

1. A digital buffer circuit positioned at one end of a transmission line and comprising 5 switches that drive the two conductors of the transmission line;
a 1^{st} switch capable of establishing a path between said 1^{st} conductor and a voltage Vhi;
a 2^{nd} switch capable of establishing a path between said 1^{st} conductor and a voltage Vlo;
a 3^{rd} switch capable of establishing a path between said 2^{nd} conductor and a voltage Vhi;
a 4^{th} switch capable of establishing a path between said 2^{nd} conductor and a voltage Vlo;
a 5^{th} switch capable of connecting said two conductors.

2. The circuit of claim 1 where said paths that may be established by said 1^{st}, 2^{nd}, 3^{rd} and 4^{th} switch each has a resistance Z₀/2, where Z₀ is the characteristic impedance of the transmission line and where said path that may be established by said 5^{th} switch has a resistance which is significantly lower than Z₀.

3. The circuit of claim 2 where said transmission line is terminated by a high impedance at the receiving end, such that the receiving end's impedance is significantly higher than Z₀.

4. The circuit of claim 3, where said 1^{st} and 4^{th} switch are closed and said 2^{nd}, 3^{rd} and 5^{th} switch are open when a logical ‘1’ is steadily signaled and where said 2^{nd} and 3^{rd} switch are closed and said 1^{st}, 4^{th} and 5^{th} switch are open when a logical ‘0’ is steadily signaled.

5. The circuit of claim 4 where a change from a logical ‘1’ to a logical ‘0’ is accomplished through a sequence of operations comprising first closing said 5^{th} switch and open said 1^{st} and 4^{th} switch, secondly wait a period until just before the reflected wave returns to the driving circuit, thirdly close said 2^{nd} and 3^{rd} switch and fourthly open said 5^{th} switch still before the reflected wave has returned.

6. The circuit of claim 5 where further a change from a logical ‘0’ to a logical ‘0’ is accomplished through a sequence of operations comprising first closing said 5^{th} switch and open said 2^{nd} and 3^{rd} switch, secondly wait a period until just before the reflected wave returns to the driving circuit, thirdly close said 1^{st} and 4^{th} switch and fourthly open said 5^{th} switch still before the reflected wave has returned.

7. The circuit of claim 1 where said switches are implemented using MOSFETs (Metal-Oxide Semiconductor Field-Effect Transistors) in an integrated circuit.

8. The circuit of claim 6 where the control logic that opens and closes said switches, determines the arrival of said reflected wave by sensing the voltages of said two conductors of the transmission line at the transmitting end.

9. The circuit of claim 8 where further said control logic measures the travel time during operation, stores the measured value and uses the stored value to determine the delays used subsequently.

10. The circuit of claim 8 where further said control logic is implemented along with said switches within the same integrated circuit.
